(19) United States
(12) Patent Application Publication
(10) Pub. No.: US 2011/0303259 A1
(43) Pub. Date: Dec. 15, 2011

(54) UTILIZATION OF GLASSES FOR PHOTOVOLTAIC APPLICATIONS

(76) Inventors: Jörg Fechner, Weiden (DE); Franz Ott, Konnersreuth (DE); Burkhard Speit, Mainz (DE)

(21) Appl. No.: 13/157,469

(22) Filed: Jun. 10, 2011

(30) Foreign Application Priority Data
Jun. 10, 2010 (DE) 10 2010 023 366.8

(51) Int. Cl. H01L 31/02

(52) U.S. Cl. 136/243

(57) ABSTRACT

Utilization of a glass for photovoltaic applications, whereby the glass has a water content of <25 mMol/liter, for example >1 mMol/liter. The used glasses may have a transformation temperature Tg in an approximate range of >580° C., a processing temperature (“VA”) in the range of approximately 1150° C. and a thermal heat expansion coefficient in the range of approximately 7 to 11×10⁻⁶/K. These glasses may be used in a high temperature process without releasing semiconductor toxins such as iron, arsenic and boron, and are suitable for Cd—Te or for CIS or respectively CIGS photovoltaic applications since the processing ability/deposition compared to traditionally used soda lime glasses can occur at higher temperatures due to higher temperature stability.

### BACKGROUND OF THE INVENTION

1. Field of the Invention

The present invention relates to glasses for photovoltaic applications.

2. Description of the Related Art

Photovoltaic is the direct conversion of solar energy into electric energy. The photovoltaic conversion occurs with solar cells—in larger units as so-called solar modules—in photovoltaic systems. This type of power generation finds use, for example, on roof surfaces, in parking ticket meters, in pocket calculators, on noise control walls and in open spaces. The produced electricity can be used locally, stored in accumulators or fed into power grids. If the energy is fed into the public power grid, the direct current is converted into alternating current by a dc-ac converter.

Solar cells are categorized according to various criteria. The most common criterion is the material thickness, for example thick film and thin film cells. A further criterion is the material used. By far the most common material used is silicon, like monocrystalline cells (c-Si), polycrystalline or multicrystalline cells (poly-Si or mc-Si), amorphous silicon (a-Si) and crystalline silicon, for example micro-crystalline silicon (μc-Si). Semiconductor materials are also used: for example in III-V-semiconductor solar cells such as GaAs-cells, II-VI-semiconductor solar cells such as CdTe (cadmium telluride) cells, or I-III-VI-semiconductor solar cells, especially CIS (copper indium diselenide) or CIGS solar cells (Chalcopyrite, engl. copper, indium, gallium, sulfur or selenium). CIGS is the abbreviation for Cu(In₁₋ₓ,Gaₓ)(S_{1-y}, Se_{y})₂ and is a known thin film technology for solar cells and is the abbreviation of the used elements of copper, indium, gallium, sulfur or selenium. Important examples are Cu(In,Ga)Se₂ (copper-indium-gallium-diselenide) or CuInS₂ (copper-indium-disulfide).

Thin film solar cells are found in different variations, depending on substrate and evaporated materials. Compared to crystalline solar cells of silicon wafers, thin film cells are approximately 100-times thinner. Thin film cells distinguish themselves from traditional solar cells (crystalline solar cells based on silicon wafers) first and foremost through the layer thicknesses of the materials used. One advantage of the thin film technology is a comparatively short value realization sequence, since semiconductor-, cell- and module production are a single production source. Especially thin film solar cells on the basis of composite semiconductors, such as for example CdTe or CIGS, display an excellent stability, as well as very substantial energy conservation efficiencies. Composite semiconductors distinguish themselves first and foremost in that they are direct semiconductors and already absorb the sunlight effectively in a relatively thin layer (approximately 2 micrometers (μm). With the assistance of thin film technology especially durable modules can be produced which offer stable efficiencies over many years. An additional strength of thin film solar cells is that they can be produced more easily and with larger surfaces. Therefore, they represent the greatest market share today.

The deposition technologies for such thin photoactive layers require high processing temperatures in order to achieve high efficiency levels. Typical temperature ranges are between 450 to 600° C., whereby the maximum temperature is limited practically only by the substrate. For large surface applications glass is generally used as the substrate. As a rule, this is generally soda lime float glass (window glass), which is used due to economic considerations, especially due to low costs and because of its thermal expansion coefficients (CTE, coefficient of thermal expansion) which are approximately adapted to the semiconductor layers. Solar cells in which a chalcopyrite semiconductor layer is applied onto a soda lime glass as a substrate are described, for example, in DE 43 33 407 C1 and WO 94/07269 A1.

Cost reduction plays an ever increasing roll for the thin film technology in photovoltaics. Reduction in costs can above all be achieved by reducing material consumption, shortening of the process duration and higher throughput associated with this, as well as an increased product yield.

Soda lime glass has a transformation temperature of approximately 490°-520° C. and therefore makes all following processes above 525° C. (in CIGS coating usual processing temperatures 530° C.—currently maximum 580° C.) difficult, since it leads moreover to so-called “sagging” in flat glasses or respectively “bowing” in tubular glasses, in other words to warping and bending. This is all the more applicable the larger the substrate is which is to be coated and the closer the processing temperature comes to the transformation temperature (Tg) of the glass, or respectively exceeds it. Warping and bending cause problems, especially in so-called inline-processes and systems and thereby clearly impair the throughput and yield.

Moreover it is generally known that an improvement in the electric characteristics of thin film solar cells on composite semiconductor basis can be achieved if these are deposited at higher temperatures, that is >550° C. It would therefore be desirable to conduct the deposition process of composite semiconductor thin films at higher temperatures in order to thereby achieve higher deposition- and cooling rates, as well as an increased efficiency capability of the photovoltaic component. As already mentioned, this can be achieved with soda lime glass as the substrate.

Numerous glasses for use in photovoltaic applications are known from the current state of the art. An alternative for soda lime glass as the substrate glass for thin film photovoltaic module on composite semiconductor basis is described, for example in DE 100 05 088 C1. DE 100 05 088 C1 discloses an alkaline alumoborosilicate glass. However, its thermal expansion coefficient (CTE) α_{20/300} is in a range of between 4.5 and 6.0×10⁻⁶/K which is consistent with the CTE of the first layer, that is to say the back contact (for example of molybdenum). Layer adhesion of a CIGS layer is therefore not guaranteed on such substrates. The glass contains in addition up to 8 weight % B₂O₃ which can be subject to evaporation/outward diffusion from the substrate in particular at high temperatures, that is >550° C. and which acts as semiconductor toxin in the CIGS system. A substrate would be desirable which may contain boron, which does not evaporate and is, therefore, non-toxic for the deposition process and for the semiconductor layer.

JP 11-135819 A further describes a solar cell on composite semiconductor basis, whereby the glass substrate has a similar composition to soda lime glass. These glasses however contain a high proportion of alkaline earth ions which lead to the mobility of the alkaline ions in the substrate being drastically reduced, or respectively prevented. It is generally known that alkaline ions play an important role during deposition of the thin films of the composite semiconductor and it is therefore desirable to have a substrate for the deposition process which allows a release of alkaline ions which is homogeneous both in terms of physical location and also time.

DE 10 2006 062 448 A1 further discloses a photovoltaic module comprising an electrode layer, thin film silicon and a converter plate of doped glass and/or doped glass ceramic, whereby the converter plate consisting of doped glass or glass ceramic has a calculated index n of at least 1.49 and is doped with at least one nonferrous heavy metal and/or at least one rare earth element. Due to the converter plate of doped glass and/or doped glass ceramic the photovoltaic module leads to reduced surface reflection losses. The photovoltaic module moreover has a water content of less than 40 millimole/liter (mMol/l). The nonferrous heavy metal is selected from MnO₂, CrO₃, NiO and/or a combination thereof. The rare earth elements are selected from bivalent or trivalent oxides and fluorides of samarium, europium, thulium, terbium, yttrium and ytterbium and or combinations thereof. The glasses according to DE 10 2006 062 448 A1 relate to completely different glasses which are not comparable to the inventively utilized glasses.

Hitherto the current state of the art rarely considered that the water content in the glasses could be of significance for use in solar cells. The only document in the current state of the art addressing this is DE 10 2009 020 954 (corresponds to DE 10 2009 050 987 B3). In DE 10 2009 020 954 a multicomponent substrate glass containing Na₂O is described which has a water content in the range of 25 to 80 mMol/liter, determined based on the intensity of the β-OH stretching vibration in a range of 2700 nanometers (nm) in the IR-spectrum. These glasses are suitable for substrate glasses for thin film solar cells only if their water content is at least 25 mMol/liter. This is based on the assumption that only at a water content of 25 mMol/liter and higher the semiconductor toxins such as iron, arsenic and boron contained in the glass are present chemically bonded and can, therefore, no longer get from the glass into the semiconductor. In the described glass compositions, a high sodium ionic mobility in the glass at temperatures of >600° C. continues to play a role. Here, the described higher water content is also an essential factor. According to DE 10 2009 020 954 high sodium content together with the high water content of 25 to 80 mMol/liter improves the efficiency of a photovoltaic solar cell, especially on the basis of the CIGS technology.

What is needed in the art is an improved glass for photovoltaic applications which avoids the disadvantages of the current state of the art. In particular, there is a need in the current state of the art for an improved thin film solar cell with a higher efficiency level.

### SUMMARY OF THE INVENTION

The present invention provides glasses for photovoltaic applications which have a water content of <25 mMol/liter, for example approximately <20 mMol/liter, approximately <15 mMol/liter, or approximately <10 mMol/liter.

Surprisingly, and in complete renunciation of the current state of the art according to De 10 2009 020 954, glasses having water contents below 25 mMol/liter are also suited for photovoltaic applications. This is unexpected, since according to DE 10 2009 020 954 only glasses having high water contents of 25 to 80 mMol/liter can be used in photovoltaic applications.

In the production of semiconductors it must generally be avoided that semiconductor toxins get into the layers, since these drastically reduce the efficiencies of the layer. Especially in high temperature processes, for example in the production of CIGS-based solar cells, it must be avoided that semiconductor toxins, such as iron, arsenic or boron evaporate or diffuse from the glass and get into the semiconductor layer. Semiconductor toxins are elements or compounds which impair the efficiency of the semiconductor which, among other problems, become active recombination centers and can lead to occurrence of open circuit voltage and short circuit current. Surprisingly it has now been found that glasses can be used in a high temperature process without releasing semiconductor toxins such as iron, arsenic and boron if they have a water content of <25 mMol/liter, for example approximately <20 mMol/liter, approximately <15 mMol/liter and <10 mMol/liter. The water content hereby refers not only to free water which may be present, but also to H₂O in the form of water of crystallization (complex-bound water H₂O) as well as to water as a so-called “hydrate cover” around cations and also anions. If semiconductor toxins are present in the selected glass compositions these are bound chemically through the presence of water and cannot leave the glass, even at high temperatures such as >550° C. Also, the diffusion of the semiconductor toxin in water can be reduced or even prevented through low water content.

### DETAILED DESCRIPTION OF THE INVENTION

The lower limit for the water content on the glasses used is, for example at approximately >1 mMol/liter, approximately >2 mMol/liter, or approximately >5 mMol/liter. According to the present invention, the glasses should not be completely free of water. Although this can be advantageous in some individual cases, it is not so according to the present invention since a possible conductor toxin in the glass can still be bound through the water which is present. For applications in the photovoltaic area the water content in the glass which is being used may be in the range of between approximately 5 mMol/liter and 25 mMol/liter. Semiconductor toxins are chemically bound to a sufficient extent through the remaining water content in the glass and can therefore not easily get from the glass into the semiconductor. Moreover it was noticed that a water content of more than 25 mMol/liter can be disadvantageous in particular for photovoltaic applications for the CIGS area (copper-indium-gallium-sulfur or selenium), since the efficiency capacity of a photovoltaic solar cell can decrease.

An additional advantage of the water content of the glass according to the present invention in the range of between approximately 5 and 25 mMol/liter is that the characteristics of the glasses are not negatively influenced. Water contents of more than 25 mMol/liter can in contrast be responsible for changes in the glass characteristics which can have a negative effect.

Determination of the quantitative water content occurs within the scope of the present invention as disclosed in DE 10 2009 020 954 by means of the OH-stretching vibration in a range of around 2700 nanometers (nm) of an IR spectrum, for example with a commercial Nicolet-FTIR spectrometer with attached computer evaluation. For this purpose, a wave length range of approximately 2500 to 6500 nm is measured first and then the absorption maximum determined at around 2700 nm. The absorption coefficient a is subsequently calculated with the sample thickness d, the internal transmission Ti and the reflection factor P as follows:

α=1/d*lg(1/Tᵢ) [cm⁻¹]

whereby Tᵢ=T/P with transmission T. The water content is then calculated from

c=α/e,

whereby e is the practical extinction coefficient [l*Mol⁻¹*cm⁻¹] and is applied for the above referenced evaluation range as a constant value of e=110 l*Mol⁻¹*cm⁻¹, formulated to the Mol H₂O. The e-value was taken from the works of H. Frank and H. Scholze from the “Glastechnischen Berichte” (glass technological reports), 36th year of publication, issue 9, page 350.

Adjustment of the water content in glasses to <25 mMol/liter can be achieved in different ways. This can, for example, be achieved by targeted selection of the starting materials and the process conditions during production of the glass. Lowering of the existing water content can for example be achieved in that additional undesirable water is not introduced into the glass either in the starting materials or during the production of the glass. The starting materials may, for example, be specially dried. Moreover, selecting particularly suitable refining agents, for example sulfite or chloride, can also contribute to the reduction of the water content. Furthermore, the melting conditions can be controlled in such a way that as little water as possible can get into the molten glass. In an embodiment of the present invention, the glass is melted in melting tanks which, based on their fuel and/or heating technology, only bring low contents of H₂O into the glass. These are, for example, fully electric heating systems or conventional heating systems (gas/oil) whereby through appropriate shielding and/or control of the system the water content can be reduced in a suitable manner. For example very dry air can be blown through the system. Another option to reduce the water content in the glass to below 25 mMol/liter is through the selection of a suitable glass composition. An increase of the water content to the range according to the present invention can, for example, be achieved by targeted selection of water-rich raw materials with water in the crystal lattice, for example Al(OH)₃ instead of Al₂O₃. An additional possibility is to realize a gas atmosphere rich in oxygen in the melting process, also known as “oxyfuel”, which can raise the water content in the glass in order to be adjusted to the range defined by the present invention.

Glasses according to the present invention not only have a water content of <25 mMol/liter, but also have a transformation temperature Tg in the range of >580° C., for example >600° C. At the same time, glasses with a processing temperature (“VA”) in the range of <1270° C., for example <1200° C. or <1150° C. may be utilized. Additionally, the glasses according to the present invention produce a characteristic thermal expansion in the range of approximately 7 to 11×10⁻⁶/K (thermal heat expansion coefficient), for example approximately 8 to 10×10⁻⁶/K, or approximately 8.5 to 10×10⁻⁶/K in the temperature range of approximately 20° to 300° C.

In order to be able to convert these characteristics, especially a high transformation temperature Tg and a relatively low processing temperature, the glass of the present invention may receive high contents of Na₂O of >10 weight %, for example >12 weight %, or >15 weight %. Also for special applications of the glasses of the present invention as substrate glasses, for example as CIGS substrate glasses, a Na₂O content of >10 weight % is an essential characteristic. Sodium contributes hereby significantly to the increase of the efficiency level, in that Na-ions can diffuse into CIGS layer. The high sodium content, therefore, is substantially contributory to achieving a high Tg value simultaneously with a low processing temperature.

Because of the high Na₂O content of >10 weight %, for example >12 weight %, or >15 weight %, it is also especially easy to hold the thermal heat expansion or respectively the thermal heat expansion coefficient (CTE) in the range mentioned above which is generally achieved with soda lime glasses (alkali-alkaline earth-silicate glasses), and to reduce the processing temperature into the range of soda lime glasses.

An additional advantage of using a high sodium content is that sodium is a positive influence on the crystallite structure and crystal density but also on the crystallite size and orientation of the semiconductor layer. Essential aspects appear to be the improved chalcogen incorporation into the crystal lattice, as well as passivation of grain boundaries. Considerably better semiconductor properties result from this, especially a reduction of the recombination in the bulk material and thereby a higher open circuit voltage. This can result in higher efficiency of the solar cell.

It is further known from soda lime glasses that their release of alkaline ions from the substrate into the semiconductor layer during the deposition process is very inhomogeneous both in terms of location and time.

In contrast, the glass according to the present invention can, in addition to the characteristic as a carrier, also support the targeted release of sodium ions/-atoms in to the semiconductor. The targeted release of alkaline ions, for example sodium, both in terms of physical location and also time (over the coating surface) homogeneously over the entire semiconductor deposition step is of decisive importance for the production of high efficiency solar cells based on composite semiconductors, especially with the measure that additional processing steps, such as doping of sodium can be omitted, in order to realize a cost effective process. The glasses according to the present invention are not to be doped with compounds selected from MnO₂, CrO₃, NiO and/or a combination thereof; glasses according to the present invention are also not to be doped with compounds selected from bivalent or trivalent oxides and fluorides of samarium, europium, thulium, terbium, yttrium and ytterbium and or combinations thereof.

The substrate glass may release Na-ions/Na-atoms at temperatures around Tg, which assumes an increased movability of the alkaline ions. Surprisingly it has now been shown that the movability of alkaline ions in glasses with the water content defined by the present invention is provided to a great extent. The ion movability of the sodium ions and their easier exchangeability is positively influenced by low residual water contents in the glass structure. For glass substrates which, due to the low water content, display a high alkaline ion movability, the alkaline ions can be homogeneously released spatially over the entire substrate area into the layers located above same, or respectively be diffused through these. The release of the alkaline ions does also not discontinue at higher temperatures, i.e. >600° C. In a high temperature process, composite semiconductor layers can ideally experience epitaxial growth, in other words, a homogeneous crystal growth across the surface, and a higher yield associated with this can be realized, as well as the assurance of a sufficiently large alkaline ion reservoir during the deposition process.

The glasses to be used according to the present invention are suitable for technologies on the basis of Cd—Te as well as technologies which are based on copper-indium-gallium-sulfur-selenium, so-called CIS or CIGS. The glasses according to the present invention are suited as substrate glass/superstrate glass or as cover glass, for example for thin film photovoltaic. Superstrate glasses are substrate glasses whereby the substrate glass essentially also functions as cover glass, since in thin film photovoltaic the coated glass is “turned over” and the layer is then positioned on the underside and the light impinges through the substrate glass onto the photovoltaic layer.

The glasses according to the present invention present an alternative to soda lime glasses, especially in the area of the photovoltaic, and can replace these advantageously, since in the separation deposition of semiconductor layers higher processing temperatures can be used than with conventional soda lime glasses, without the substrate deforming in an unfavorable manner. Bent substrate glass is problematic, for example, in process chamber locks and can lead to a substantial loss in yield. In addition it is enormously advantageous for the lamination process if the solar cells are not bent. Here too, a substrate which is not totally planar can lead to a loss in yield.

When using a substrate glass with a higher Tg than standard soda lime glass, higher process temperatures during the semiconductor deposition become possible. Higher separation temperatures during the chalcopyrite formation, however, lead to a substantial reduction of crystal defect phases to below the detection limit. On the other hand, no particularly high temperatures are necessary for the melting and hot forming process of the glass, thereby providing the possibility of a cost effective production.

The higher processing temperatures surprisingly also provide for faster processing, for example, processes on the crystal formation front proceed faster and the installation of the elements onto the appropriate crystal locations is accelerated. In the case of sequential processing, a fundamental mechanism is the diffusion of the individual atoms to the surface where the reactions with the chalcogen-atoms occur. A higher temperature causes a higher diffusion speed of the elements to the reaction surface and thereby a faster transport of the elements which are necessary for crystal formation to the crystallization front. A desired higher temperature during the coating process, therefore, leads to high deposition rates and therefore to a very good crystalline quality of the produced layers. Moreover, during cooling after application of the semiconductor layers no layers peel off since the substrate glass may have a suitable thermal heat expansion at the semiconductor applied on it (i.e., approximately 8.5×10-6/K for CIGS).

The glasses according to the present invention are therefore suited for Cd—Te or for CIS or respectively CIGS photovoltaic applications, for example substrate glass and/or superstrate glass and/or cover glass. The glasses of the present invention therefore find application, for example as thin film solar cell-substrates or -superstrates or -cover glasses. The glasses according to the present invention are suitable for thin film photovoltaic since considerably less photoactive material is required for an efficient conversion of sun light than with conventional crystalline, silicon based solar cells. The low semiconductor material usage and the high automation of the production process result in clear cost reductions with this technology.

The glass according to the present invention may be utilized as a substrate for a thin film solar cell. A solar cell is basically not subject to any restrictions in regard to their shape or shape of the substrate glass. The thin film solar cell may, for example, be planar, curved, spherical or cylindrical in shape, so the substrate is also correspondingly planar, curved, spherical or cylindrical in shape. The thin film solar cell is, for example, a substantially planar (flat) thin film solar cell or a substantially tubular thin film solar cell, whereby flat substrate glasses or tubular substrate glasses are utilized. In the case of a tubular thin film solar cell the outside diameter of a tubular substrate glass of the solar cell is, for example approximately 5 to 100 millimeters (mm) and the wall thickness of the tubular substrate glass may be, for example approximately preferably 0.5 to 10 mm.

A thin film solar cell which uses glass according to the present invention is advantageously produced according to the method described in DE 10 2009 020 954, disclosure of which is included by reference in its totality into the current disclosure. A thin film solar cell of this type including the glass substrate which is to be used according to the present invention then provides an absolute higher efficiency in excess of 2% compared to the current state of the art.

With the technology of the present invention, cost effective highly efficient integrated photovoltaic modules on the basis of composite semiconductors, such as CdTe or CIGS can be provided. The reduced costs result primarily from the higher efficiencies, faster processing times and thereby a higher throughput, as well as higher yields.

The present invention accordingly provides a substrate glass which, in addition to its carrier function, is credited with an active role in the semiconductor production process and which distinguishes itself in particular through an optimum CTE adaptation at high temperatures to the photoactive composite semiconductor thin film, as well as through great thermal and chemical stability. A provided thin film solar module can therefore be flat, spherical, cylindrical or of another geometrical shape. According to an additional embodiment of the present invention the glass can also be colored.

Glasses according to the present invention may be glasses containing silicate, such as alumina-silicate glasses, borosilicate glasses, boroalumina-silicate glasses or soda lime glasses having a water content of <25 mMol/liter, for example <15 mMol/liter, <20 mMol/liter, or <10 mMol/liter. Glasses according to the present invention may include comprise an SiO₂-content in the range of approximately 40 to 69 weight %, for example approximately 40 to <61 weight %, approximately 45 to <61 weight %, approximately 49 to <61 weight %, or approximately 49 to 60 weight %. Such a SiO₂ content has the advantage in use in the area of photovoltaic that less water can diffuse into the CIS or CIGS layer. Such glasses moreover possess an alkaline diffusion, for example sodium diffusion.

No compounds selected from MnO₂, CrO₃, NiO and/or a combination thereof are present in the glasses of the present invention. Also, no compounds selected from bivalent or trivalent oxides and fluorides of samarium, europium, thulium, terbium, yttrium and ytterbium and/or combinations thereof are to be present in the glasses of the present invention.

Glasses according to the present invention are, for example, alumina-silicate glasses, including the following glass composition (in weight %) on oxide basis:

| | |
|---|---|
| SiO₂ | approximately 49-69 weight %, for example |
| | approximately 49-<61 weight %; |
| B₂O₃ | approximately 0-2 weight %, for example |
| | approximately 0 weight %; |
| Al₂O₃ | approximately >4.7-19 weight %, for example |
| | approximately >5-17 weight %; |
| Li₂O | approximately 0-4 weight %, for example |
| | approximately 0-<0.3 weight %; |
| Na₂O | approximately >10-18 weight %, for example |
| | approximately >15-18 weight %; |
| K₂O | approximately >0-8 weight %, for example |
| | approximately >0-<5 weight %, or |
| | approximately >0-<4 weight %; |
| sum of Li₂O + | approximately >10-19 weight %; |
| Na₂O + K₂O | |
| MgO | approximately 0-6 weight %; |
| CaO | approximately 0-<5 weight %; |
| SrO | approximately 0-7 weight %, for example |
| | approximately 0-<0.5 weight %; |
| BaO | approximately 0-10 weight %, for example |
| | approximately 1-9 weight %, or approximately |
| | 2-4 weight %; |
| sum of MgO + | approximately 7-weight %; |
| CaO + SrO + BaO | |
| F | approximately 0-3 weight %; |
| TiO₂ | approximately 0-6 weight %, for example |
| | approximately >0.1-5 weight %; |
| Fe₂O₃ | approximately 0-0.5 weight %; |
| ZrO₂ | approximately >0-6 weight %, for example |
| | approximately 1-6 weight %, or approximately |
| | 1.5-5 weight %; |
| sum BaO + ZrO₂ | approximately 2-15 weight %, for example |
| | approximately 3-15 weight %, |
| ZnO | approximately 0-3 weight %, for example |
| | approximately 0-2 weight %, or approximately |
| | 0.3-1.8 weight %; |
| CeO₂ | approximately 0-3 weight %; |
| WO₃ | approximately 0-3 weight %; |
| Bi₂O₃ | approximately 0-3 weight %; and |
| MoO₃ | approximately 0-3 weight % . |

The water content of the glass according to the present invention is <25 mMol/Liter, for example >5 mMol/Liter. Conventional refining agents, such as for example sulfate, chloride, Sb₂O₃, As₂O₃, SnO₂, can be added to the above glass/molten glass.

According to the present invention the above alumina-silicate glasses may be used. They include as a main component SiO₂ and Al₂O₃, as well as alkaline and alkaline earth oxides and may further include additional components.

The glass according to the present invention may contain at least approximately 49 weight %, for example at least approximately 50 weight %, or at least approximately 52 weight % of SiO₂. The maximum amount of SiO₂ is approximately 69 weight %. An exemplary SiO₂ content is in a range of approximately 49 to <61 weight %, for example in the range of approximately 49 to 60 weight %.

The minimum approximate amount of Al₂O₃ is >4.7 weight %, for example >5 weight %, or >8 weight %. The approximate Al₂O₃ content is for example <19 weight %, <17 weight % or ≦11 weight % in order to provide for a good meltability. Exemplary Al₂O₃ content ranges include approximately >5 to 17 weight %, for example from approximately 8 to 12 weight %. The contents can be manipulated according to the application purpose. Exceeding the Al₂O₃ content of approximately 19 weight % has the disadvantage of high material costs and diminished melting capabilities. Falling below an Al₂O₃ content of approximately 4.7 weight % has the disadvantage that the chemical stability of the glass is diminished and the tendency for crystallization increases.

Of the alkaline oxides lithium, sodium and potassium, sodium are of particular significance as already explained. According to the present invention, Na₂O is contained in an approximate amount of >10 to 18 weight %, for example >11 to 18 weight %, >12 to 18 weight %, or >15-18 weight %. The approximate K₂O content is >0 to 8 weight %, for example >0 to <5 weight %, or >to <4 weight %. According to the present invention the approximate Li₂O content is 0 to 4 weight %, for example 0 to 1.5 weight %, or 0 to <0.3 weight %. The addition of Li₂O can serve for the adjustment of the thermal heat expansion (CTE) and to lower the processing temperature. The Li₂O content of the glass according to the present example may, for example, be at <0.3 weight %, or completely free of Li₂O. To date there are no indications that Li₂O would act similar to Na₂O since its diffusion is presumably too high. Moreover, Li₂O is expensive as a raw material, so that it is advantageous to use lesser amounts.

Exceeding the respective alkaline oxide content has the disadvantage that the melting capability deteriorates. Falling below the respective alkaline oxide content has the disadvantage that the meltability is decreased. The approximate sum of Li₂O+Na₂O+K₂O is in the range of >10 to 19 weight %, for example in the range of >12 to 19 weight %.

Calcium, magnesium, barium and, to a minor extent strontium, are used as alkaline earth oxides. CaO is used in an approximate range of 0 to <5 weight %, for example 0.3 to <4.3 weight %, 0.5 to <3 weight %, or 0.5 to <1.5 weight %. MgO is used in an approximate range of 0 to 6 weight %, for example 0 to 5 weight %, 0.1 to 4 weight %, or 0.5 to 3.5 weight %. MgO can be utilized to improve the crystallization stability and to increase the transformation temperature Tg. However, MgO may also be totally left out of the glass composition according to the present invention (MgO=0 weight %).

BaO is used in an approximate range of 0 to 10 weight %, for example 1 to 9 weight %, 2 to 8 weight %, or 2 to 4 weight %. The addition of BaO can be used to increase the transformation temperature Tg of the glass composition. However, BaO may also be totally left out of the glass composition of the present invention (BaO=0 weight %). The advantages of a low or no BaO content are essentially the low density and thereby the weight reduction of the glass as well as the cost savings of expensive components. The low density is advantageous in transporting the glass for further processing, especially if the end products which are produced from the glass are installed in portable devices. The weight reduction in the glass amounts is for example to >2% (at an approximate BaO content in the range of approximately 3 to <4 weight %), for example >5% (at an approximate BaO content in the range of approximately 2 to 3 weight %) or >8% (at an approximate BaO content in the range of approximately 0 to 1 weight %). An additional advantage of a glass with little or no BaO content is that barium ions, for example in the form of soluble barium compounds which are considered toxic, can be reduced or totally left out. By reducing or eliminating the presence of the BaO component, an additional clear cost advantage results since BaO is relatively expensive. This accumulates in large-scale glass production and therefore provides considerable advantages.

SrO is contained in the glass according to the present invention in an approximate range of 0 to 7 weight %, for example 0 to <2.5 weight %, or in a range of 0 to 0.5 weight %. SrO generally serves to increase the transformation temperature Tg of the glass. SrO may not be contained in the glass composition of the present invention (SrO=0 weight %). Special disadvantageous effects as are maintained in the current state of the art could hereby not be noticed.

According to the present invention, the sum total of MgO+CaO+SrO+BaO is in the range of approximately 7 to 15 weight %, for example in the range of 8 to 14 weight %, or in the range of 8.5 to 14 weight %.

According to the present invention B₂O₃ is present in an amount of approximately 0 to 2 weight %, for example approximately 0 to 1 weight %, or 0 to 0.5 weight %. According to an embodiment of the present invention, the glass does not contain B₂O₃. B₂O₃ is toxicologically hazardous (teratogenic or respectively toxic to reproduction) and is also an expensive component which significantly increases the compound costs. Higher portions of B₂O₃ also have the disadvantage that they evaporate during the glass melt, precipitate in the exhaust gas area with negative effects and generally alter the glass composition. It has been shown that a B₂O₃ content in a substrate glass of more than approximately 1 weight % can have a negative effect on the efficiency of a solar cell, since boron atoms get from the substrate glass into the semiconductor layers, either through evaporation or diffusion where they cause probable defects, which are electrically active and can reduce the efficiency of the cell through increased recombination.

In addition, ZrO₂ is contained in an approximate amount of >0 to 6 weight %, for example approximately 1 to 6 weight %, or approximately 1.5 to 5 weight %.

According to the present invention, the sum of BaO+ZrO₂ is in the range of approximately 2 to 15 weight %, for example in the range of approximately 3 to 15 weight %.

Moreover other components such as, for example, WO₃, MoO₃, Bi₂O₃, CeO₂, TiO₂, Fe₂O₃, ZnO, F and/or Cs₂O or also other components can be present, independent of each other.

WO₃, MoO₃ and Bi₂O₃ are present in the alumina-silicate glasses of the present invention, independent of each other, respectively in an amount of approximately 0 to 3 weight %. These components may serve to adjust the UV-edge of the glass and can also find use as redox-buffer in refining.

TiO₂ and also CeO₂ can generally be added for UV blocking of the glass. Depending on the area of application, the glass of the present invention may be in the form, for example, of a cover glass/cover tube and can be doped with, for example, TiO₂ and/or CeO₂ in order to keep away damaging UV radiation from components which are located beneath the glass. According to the present invention, the TiO₂ content is in a range of approximately 0 to 6 weight %, for example in a range of >0.1 to 5 weight %, or in an approximate range of >0.1 to 4 weight %. However, a content of approximately 0.1 to 2 weight % may be utilized, since toxic refining agents, such as As₂O₃ and Sb₂O₃ can be completely dispensed with. According to the present invention CeO₂ is in a range of approximately 0 to 3 weight %.

Fe₂O₃ finds use in an amount of approximately 0 to 0.5 weight % and normally serves to adjust UV-blocking, but can also be used as a redox-buffer in refining.

In addition, fluorine in the form of fluorides, for example NaF, can be added to the glass according to the present invention in order to improve the meltability. The amount which is added into the glass composition is approximately 0 to 3 weight %.

Conventional refining agents can be used in as far as they do not negatively influence the chemical and physical properties of the glass composition of the present invention. For example, refining with sulfates, chlorides, Sb₂O₃, As₂O₃ and/or SnO₂ is possible. The refining agents are respectively contained in the glass in an approximate amount of >0 to 1 weight %, whereby the minimum amount is for example 0.1, in particular 0.2 weight %.

The present invention is explained in further detail below with reference to examples which will demonstrate the technology of the present invention, but are not intended to limit same.

### EXAMPLES

Glass compositions were selected according to the technology of the present invention and glasses produced therefrom. The glasses were melted in 4-liter platinum crucibles from conventional raw materials. In order to ensure a residual water content in the glass, Al-raw material Al(OH)₃ was used. In addition, an oxygen burner was used in the chamber of the gas-fueled melting furnace (oxyfuel technology) in order to achieve the high melting temperatures when conducting the oxidizing melting procedure. The raw materials were introduced over a time period of approximately 8 hours (h) at melting temperatures of approximately 1580° C. and were subsequently held at this temperature for approximately 14 hours. The glass melt was then cooled by agitation within approximately 8 hours to approximately 1400° C. and was subsequently poured into a graphite mold which was preheated to approximately 500° C. Immediately after the pouring, this mold was moved into an annealing furnace which was preheated to approximately 650° C. and which cooled to room temperature at approximately 5° C./h. The glass samples necessary for the measurements were then taken from this block. Following tables 1 and 2 summarize the compositions and properties of the inventively utilized glasses.

TABLE 1

| [in weight %] | V1a | V1b | V2a | V2b | V3a | V3b |
|---|---|---|---|---|---|---|
| SiO₂ | 62.90 | 62.90 | 60.60 | 60.60 | 59.45 | 59.45 |
| B₂O₃ | | | | | 0.5 | 0.5 |
| Al₂O₃ | 17.00 | 17.00 | 17.00 | 17.00 | 11.0 | 11.0 |
| Na₂O | 12.00 | 12.00 | 12.00 | 12.00 | 12.00 | 12.00 |
| K₂O | 4.00 | 4.00 | 4.00 | 4.00 | 6.00 | 6.00 |
| MgO | 3.70 | 3.70 | 4.00 | 4.00 | 3.50 | 3.50 |
| CaO | 0.30 | 0.30 | | | 1.00 | 1.00 |
| BaO | | | | | 4.00 | 4.00 |
| SrO | | | | | | |
| ZrO₂ | | | 1.50 | 1.50 | 2.50 | 2.50 |
| TiO₂ | | | | | | |
| CeO₂ | | | 0.10 | 0.10 | | |
| SO₃ | | | | | | |
| SnO₂ | | | 0.50 | 0.50 | | |
| F | | | 0.30 | 0.30 | | |
| Sb₂O₃ | | | | | 0.05 | 0.05 |
| As₂O₃ | 0.10 | 0.10 | | | | |
| Water content | 23 | 30 | 20 | 45 | 20 | 50 |
| mMol/Liter | | | | | | |
| Sum | 100.00 | 100.00 | 100.00 | 100.00 | 100.00 | 100.00 |

TABLE 2

| [in weight.-%] | V4a | V4b | V5a | V5b | V6a | V6b |
|---|---|---|---|---|---|---|
| SiO₂ | 52.8 | 52.8 | 53.6 | 53.6 | 61.5 | 61.5 |
| B₂O₃ | — | — | — | — | — | — |
| Al₂O₃ | 13.7 | 13.7 | 14.5 | 14.5 | 16.8 | 16.8 |
| Na₂O | 11.3 | 11.3 | 11.5 | 11.5 | 12.2 | 12.2 |
| K₂O | 3.2 | 3.2 | 3.3 | 3.3 | 4.1 | 4.1 |
| MgO | 3.0 | 3.0 | 2.7 | 2.7 | 3.9 | 3.9 |
| CaO | 4.2 | 4.2 | 3.8 | 3.8 | — | — |
| SrO | — | — | — | — | — | — |
| BaO | 7.5 | 7.5 | 5.3 | 5.3 | — | — |
| ZrO₂ | 3.7 | 3.7 | 3.5 | 3.5 | 1.5 | 1.5 |
| Cl | 0.5 | 0.5 | 0.5 | 0.5 | — | — |
| SO₃ | 0.1 | 0.1 | 0.1 | 0.1 | — | — |
| ZnO | — | — | 1.2 | 1.2 | — | — |
| F | — | — | — | — | — | — |
| As₂O₃ | — | — | — | — | — | — |
| Water content | 18 | 35 | 20 | 40 | 19 | 30 |
| mMol/Liter | | | | | | |
| Sum | 100.00 | 100.00 | 100.00 | 100.00 | 100.00 | 100.00 |

Examples V1a, V2a, V3a, V4a, V5a and V6a are glass compositions which contain a water content within the inventive range. Examples V1b, V2b, V3b, V4v, V5b and V6b are glass compositions whose water content is higher than inventively required. The higher water content is disadvantageous since greater volumes of the semiconductor toxin can diffuse water into the photoactive layers and can lead to a reduction in the efficiency.

The present invention therefore describes glass compositions to be used in photovoltaics, which represent an alternative to sodium lime glasses and which, based on a water content of <25 mMol/liter possess especially advantageous properties. The water content in the glasses of <25 mMol/liter, for example <20 mMol/liter, <15 mMol/liter or <10 mMol/liter allows for these glasses to be used in a high temperature process, without releasing semiconductor toxins such as iron, arsenic or boron. The movability of alkaline ions is provided to a great measure in these glasses with low water content, so that the ion-movability of the sodium ions and their easier exchangeability through the low residual water content in the glass structure is positively influenced. The alkaline ions can be disposed spatially homogeneously over the entire substrate area into the layers arranged above, or respectively can diffuse through these.

A water content of 25 mMol/liter or more can be disadvantageous, particularly for photovoltaic applications in the CIGS-area (copper-indium-gallium-sulfur or selenium) since the efficiency of a photovoltaic solar cell can decrease. The water content in the range of between approximately 1 and 25 mMol/liter in no way influences the glass properties of the glasses negatively, whereas in contrast a water content of above 25 mMol/liter can absolutely lead to disadvantageous changes in the glass properties.

Glasses having a similar thermal expansion of approximately 8 to 10×10⁻⁶/K, but with a higher thermal load capacity (Tg) at simultaneously similar, or respectively slightly higher processing temperatures (VA) compared to soda lime glasses may be utilized. The glasses to be used according to the present invention are suited for Cd—Te or for CIS- or respectively CIGS-photovoltaic applications since processing ability/deposition compared to traditionally used soda lime glasses can occur at higher temperatures due to higher temperature stability, which provides considerable advantages.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A glass composition for photovoltaic applications, the glass having a water content of less than 25 millimoles per liter (mMol/l).

2. The glass according to claim 1, wherein said water content of the glass is less than 20 mMol/l.

3. The glass according to claim 2, wherein said water content of the glass is less than 15 mMol/l.

4. The glass according to claim 3, wherein said water content of the glass is less than 10 mMol/l.

5. The glass according to claim 1, wherein the photovoltaic application is one of Cd—Te (cadmium telluride) cells, CIS (copper indium disulfide) and CIGS (copper indium gallium diselenide) photovoltaic applications.

6. The glass according to claim 1, wherein the photovoltaic application is a thin film photovoltaic application.

7. The glass according to claim 1, wherein the glass is at least one of a substrate glass, a superstrate glass, and a cover glass.

8. The glass according to claim 1, wherein the glass is a substrate in a thin film solar cell.

9. The glass according to claim 8, wherein said substrate has one of a planar, curved, spherical and cylindrical shape.

10. The glass according to claim 1, wherein the glass has an Na₂O content of greater than 10 weight %.

11. The glass according to claim 10, wherein said Na₂O content is greater than 12 weight %.

12. The glass according to claim 11, wherein said Na₂O content is greater than 15 weight %.

13. The glass according to claim 1, wherein the glass has a transformation temperature (Tg) of greater than 580° C.

14. The glass according to claim 13, wherein said transformation temperature is greater than 600° C.

15. The glass according to claim 14, wherein the glass has a processing temperature (VA) of less than 1270° C.

16. The glass according to claim 15, wherein said processing temperature is less than 1200° C.

17. The glass according to claim 16, wherein said processing temperature is less than 1150° C.

18. The glass according to claim 17, wherein the glass has a thermal heat expansion coefficient of approximately 7 to 11×10⁻⁶/K in a temperature range of approximately 20° C. to 300° C.

19. The glass according to claim 18, wherein said thermal heat expansion coefficient is approximately 8 to 10×10⁻⁶/K.

20. The glass according to claim 19, wherein said thermal heat expansion coefficient is approximately 8.5 to 10×10⁻⁶/K.

21. The glass according to claim 20, wherein the glass composition includes in weight % on an oxide basis:

| | |
|---|---|
| SiO₂ | 49-69 weight %; |
| B₂O₃ | 0-2 weight %; |
| Al₂O₃ | greater than 4.7-19 weight %; |
| Li₂O | 0-4 weight %; |
| Na₂O | greater than 10-18 weight %, |
| K₂O | greater than 0-8 weight %, |
| MgO | 0-6 weight %; |
| CaO | 0-less than 5 weight %; |
| SrO | 0-7 weight %, |
| BaO | 0-10 weight %, |
| F | 0-3 weight %; |
| TiO₂ | 0-6 weight %; |
| Fe₂O₃ | 0-0.5 weight %; |
| ZrO₂ | greater than 0-6 weight %; |
| ZnO | 0-3 weight %; |
| CeO₂ | 0-3 weight %; |
| WO₃ | 0-3 weight %; |
| Bi₂O₃ | 0-3 weight %; |
| MoO₃ | 0-3 weight %; and |

a sum of Li₂O+Na₂O+K₂O is >10-19 weight %, a sum of MgO+CaO+SrO+BaO is 7 weight %, and a sum of BaO+ZrO₂ is 2-15 weight %, the glass including at least one refining agent, said refining agent including one of sulfate, chloride, Sb₂O₃, As₂O₃, and SnO₂.

22. The glass according to claim 21, wherein said SiO₂is in a range between 49—less than 61 weight %

23. The glass according to claim 21, wherein said B₂O₃ is 0 weight %.

24. The glass according to claim 21, wherein said Al₂O₃ is in a range between greater than 5-17 weight %.

25. The glass according to claim 21, wherein said Li₂O is in a range between 0—less than 0.3 weight %.

26. The glass according to claim 21, wherein said Na₂O is in a range between greater than 15-18 weight %.

27. The glass according to claim 21, wherein said K₂O is in a range between greater than 0—less than 5 weight %.

28. The glass according to claim 27, wherein said K₂O is in a range between greater than 0—less than 4 weight %.

29. The glass according to claim 21, wherein said SrO is in a range between 0—less than 0.5 weight %.

30. The glass according to claim 21, wherein said BaO is in a range between 1-9 weight %.

31. The glass according to claim 30, wherein said BaO is in a range between 2-4 weight %.

32. The glass according to claim 21, wherein said TiO₂ is in a range between greater than 0.1-5 weight %.

33. The glass according to claim 21, wherein said ZrO₂ is in a range between 1-6 weight %.

34. The glass according to claim 33, wherein said ZrO₂ is in a range between 1.5-5 weight %.

35. The glass according to claim 21, wherein said sum of BaO+ZrO₂ is in a range between 3-15 weight %.

36. The glass according to claim 21, wherein said ZnO is in a range between 0-2 weight %.

37. The glass according to claim 36, wherein said ZnO is in a range between 0.3-1.8 weight %.
